(19) United States
(12) Patent Application Publication
(10) Pub. No.: US 2013/0223136 A1
(43) Pub. Date: Aug. 29, 2013

(54) SRAM based on 6 transistor structure including a first inverter, a second inverter, a first pass-gate transistor, and a second pass-gate transistor

(71) Applicants: Ching-Te CHUANG, New Taipei City (TW); Shyh-Jye Jou, Hsinchu County (TW); Wei Hwang, Taipei City (TW); Yi-Wei Lin, New Taipei City (TW); Ming-Chien Tsai, Kaohsiung City (TW); Hao-I Yang, Taipei City (TW); Ming-Hsien Tu, Tainan City (TW); Wei-Chiang Shih, Taipei City (TW); Nan-Chun Lien, Hsinchu City (TW); Kuen-Di Lee, Kinmen County (TW)

(72) Inventors: Ching-Te CHUANG, New Taipei City (TW); Shyh-Jye Jou, Hsinchu County (TW); Wei Hwang, Taipei City (TW); Yi-Wei Lin, New Taipei City (TW); Ming-Chien Tsai, Kaohsiung City (TW); Hao-I Yang, Taipei City (TW); Ming-Hsien Tu, Tainan City (TW); Wei-Chiang Shih, Taipei City (TW); Nan-Chun Lien, Hsinchu City (TW); Kuen-Di Lee, Kinmen County (TW)

(73) Assignee: National Chiao Tung University, Hsinchu City (TW)

(21) Appl. No.: 13/484,497

(22) Filed: May 31, 2012

(30) Foreign Application Priority Data
Feb. 24, 2012 (TW) 101106197

(51) Int. Cl. G11C 11/40

(52) U.S. Cl. 365/154

(57) ABSTRACT

The present invention provides a 6T SRAM including a first inverter, a second inverter, a first pass-gate transistor, and a second pass-gate transistor. The first inverter zs a first pull-up transistor and a first pull-down transistor. The second inverter includes a second pull-up transistor and a second pull-down transistor. The gate of the second pull-up transistor is coupled with the gate of the second pull-down transistor, and the drain of the second pull-up transistor is coupled with the drain of the second pull-down transistor. The SRAM can measure the trip voltage, the read disturb voltage, and the write margin by controlling the first bit line, the second bit line, the GND, the first word line, and the voltage source without changing of the physic parameter of the SRAM.

### BACKGROUND OF THE INVENTION

1. Field of the Invention

The present invention provides a SRAM, particularly a 6T SRAM to measure the trip voltage, the read disturb voltage, and the write margin.

2. Description of the Prior Art

The reliability test of the integrated circuit depends on the reliability of the semiconductor device basically. The reliability is a very important factor to the integrated circuit field. As for current nano-device, the reliability plays a very important role to the smaller device and the more complicated circuit.

When the miniaturization of device and complexity of circuit are increased, the size and the operation voltage of related transistor are reduced, but the sensitivity of noise and process change will be increased at the same time. For example, when the operation of individual static memory unit is changed, the failure rate of memory unit operated at high speed will be increased. Thus, it is necessary to keep the stability of memory unit to ensure the effective preservation of information and possess required write ability. Among these, the stability is measured by the static noise margin (SNM) and the write ability is measured by the write margin.

In addition, upon testing the reliability, as the supply voltage is dropping constantly, the hot carrier effect is also dropping constantly, therefore the hot carrier has not already been the No. 1 killer of reliability, and the substitute is the Bias Temperature Instability. The Bias Temperature Instability will cause the variation of critical voltage of transistor. For example, when a negative voltage is applied on the gate, the critical voltage of P-type metal-oxide-semiconductor (PMOS) transistor will be reduced with respect to time. The variation of critical voltage is a great challenge to the operation of integrated circuit. Due to the critical voltage represents the voltage required to open the transistor in the circuit design, the variation represents the uncertain state of transistor and the risk of circuit operation.

Therefore, a SRAM based on 6 transistor structure is required to measure the trip voltage, the read disturb voltage and the write margin, in order to help the circuit designer to maintain the dynamic and long-term reliability.

### SUMMARY OF THE INVENTION

A purpose of the present invention is to provide a SRAM based on 6 transistor structure to measure the trip voltage, the read disturb voltage and the write margin without changing the process parameter of the SRAM.

Based on the above-mentioned purpose, the present invention provides a SRAM. The SRAM is consisted of 6 transistor structure. The SRAM includes a first inverter, a second inverter, a first pass-gate transistor, and a second pass-gate transistor. The first inverter includes a first pull-up transistor and a first pull-down transistor. The second inverter includes a second pull-up transistor and a second pull-down transistor. The gate of the second pull-up transistor is coupled with the gate of the second pull-down transistor, and the drain of the second pull-up transistor is coupled with the drain of the second pull-down transistor. The source of the second pull-up transistor is coupled with the source of the second pull-down transistor, and the source of the second pull-down transistor is coupled with the ground (GND).

The drain of the first pass-gate transistor is coupled with the gate of the second pull-up transistor and the gate of the second pull-down transistor. The gate of the first pass-gate transistor is coupled with the first word line, and the source of the first pass-gate transistor is coupled with the first bit line. The drain of the second pass-gate transistor is coupled with the drain of the second pull-up transistor and the drain of the second pull-down transistor. The gate of the second pass-gate transistor is coupled with the first word line. The source of the second pass-gate transistor is coupled with the second bit line. The first pull-up transistor and the first pull-down transistor are floating.

Another aspect of the present invention is to provide a SRAM to measure the trip voltage, the read disturb voltage and the write margin by controlling the first bit line, the second bit line, the first word line, the GND and the input voltage of voltage source.

As for another aspect of the present invention, the first pull-up transistor and the second pull-up transistor are P-type metal-oxide-semiconductor transistors. The first pull-down transistor, the second pull-down transistor, the first pass-gate transistor and the second pass-gate transistor are N-type metal-oxide-semiconductor transistors.

The gate of the second pull-up transistor is coupled with the source of the second pull-up transistor. The gate and drain of the second pull-up transistor are coupled with the. The first pull-up transistor and the first pull-down transistor are floating. The drain of the first pass-gate transistor is coupled with the drain of the second pull-up transistor and drain of the second pull-down transistor. The SRAM measures the read disturb voltage by controlling the first bit line, the second bit line, the first word line, the GND and the input voltage of voltage source.

As for another aspect of the present invention, the gate of the first pull-up transistor is coupled with the gate of the first pull-down transistor and the drain of the second pull-up transistor. The gate of the first pull-up transistor is coupled with the gate of the first pull-down transistor. The drain of the first pull-up transistor is coupled with the drain of the first pull-down transistor. The drain of the first pull-up transistor is coupled with the drain of the first pass-gate transistor, the gate of the second pull-up transistor and the gate of the second pull-down transistor. The source of the first pull-up transistor is coupled with the voltage source. The source of the second pull-down transistor is coupled with the GND. Among them, the SRAM measures the write margin by controlling the first bit line, the second bit line, the first word line, the GND and the input voltage of voltage source.

Therefore, a SRAM based on 6 transistor structure is required. The SRAM is consisted of an array based structure, wherein the layout of diffusion, contact layer and Poly materials do not have to be changed. The conventional 6T SRAM can be used to measure the trip voltage, the read disturb voltage and the write margin of circuit.

In order to understand the above-mentioned purposes, characteristics and advantages of present invention more obviously, the detailed explanation is described as follows with preferred embodiments and figures.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is an illustration according to the SRAM of the present invention;

FIG. 2 is an illustration of the SRAM Array consisted of the SRAM according to FIG. 1;

FIG. 3 is another illustration according to the SRAM of the present invention;

FIG. 4 is an illustration of the SRAM Array consisted of the SRAM according to FIG. 3; and

FIG. 5 is another illustration according to the SRAM of the present invention.

### DESCRIPTION OF THE PREFERRED EMBODIMENT

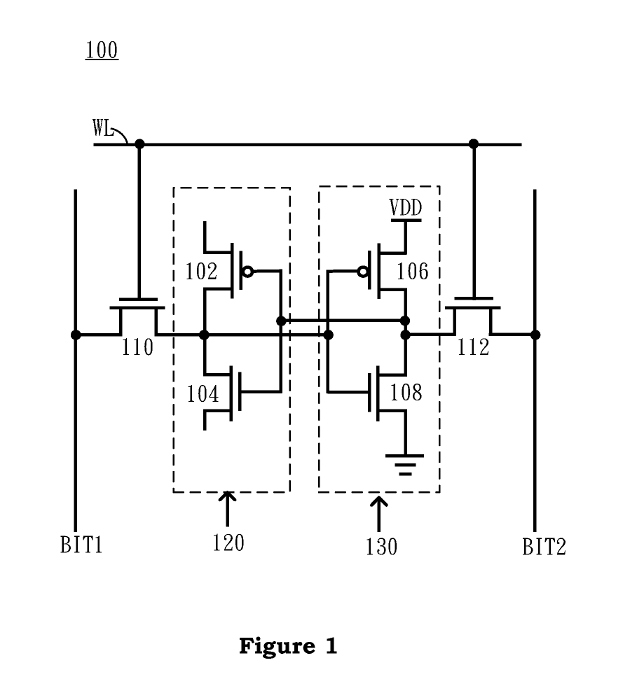

Please referring to FIG. 1, which is an illustration according to the SRAM of the present invention. The SRAM is consisted of 6 transistor structure. The SRAM 100 includes a first inverter 120, a second inverter 130, a first pass-gate transistor 110 and a second pass-gate transistor 112. The first inverter 120 is consisted of a first pull-up transistor 102 and a first pull-down transistor 104. The second inverter 130 is consisted of a second pull-up transistor 106 and a second pull-down transistor 108.

In the embodiment of FIG. 1, the SRAM is at Vₜᵣᵢₚ mode for measuring the trip voltage. In the first inverter 120, the gate of the first pull-up transistor 102 is coupled with the gate of the first pull-down transistor 104. The drain of the first pull-up transistor 102 is coupled with the drain of the first pull-down transistor 104. In the second inverter 130, the gate of the second pull-up transistor 106 is coupled with the gate of the second pull-down transistor 108. The drain of the second pull-up transistor 106 is coupled with the drain of the second pull-down transistor 108. As shown in the figure, the first pull-up transistor 102 and the first pull-down transistor 104 in the first inverter 120 are shown by the gray lines. It means the first inverter 120 and the second inverter 130 are floating, and the first inverter 120 is ineffective. The source of the second pull-up transistor 106 is coupled with the VDD. The source of the second pull-down transistor 108 is coupled with the GND. It has to describe that in the embodiment of the SRAM 100, the first pull-up transistor 102 and the second pull-up transistor 106 are P-type metal-oxide-semiconductor (PMOS) transistors. The first pull-down transistor 104, the second pull-down transistor 108, the first pass-gate transistor 110 and the second pass-gate transistor 112 are N-type (NMOS) metal-oxide-semiconductor transistors.

Referring to FIG. 1 continuously, the drain of the first pass-gate transistor 110 is coupled with the gate of the second pull-up transistor 106 and the gate of the second pull-down transistor 108. The gate of the first pass-gate transistor 110 is coupled with the first word line WL. The source of the first pass-gate transistor 110 is coupled with the first bit line BIT1.

Referring to FIG. 1 again, the drain of the second pass-gate transistor 112 is coupled with the drain of the second pull-up transistor 106 and the drain of the second pull-down transistor 108. The gate of the second pass-gate transistor 112 is coupled with the first word line WL. The source of the second pass-gate transistor 112 is coupled with the second bit line BIT2.

In the embodiment of FIG. 1, by the connection way of the first inverter 120 and the second inverter 130 of SRAM 100 is to form a circuit structure for measuring the trip voltage Vₜᵣᵢₚ.

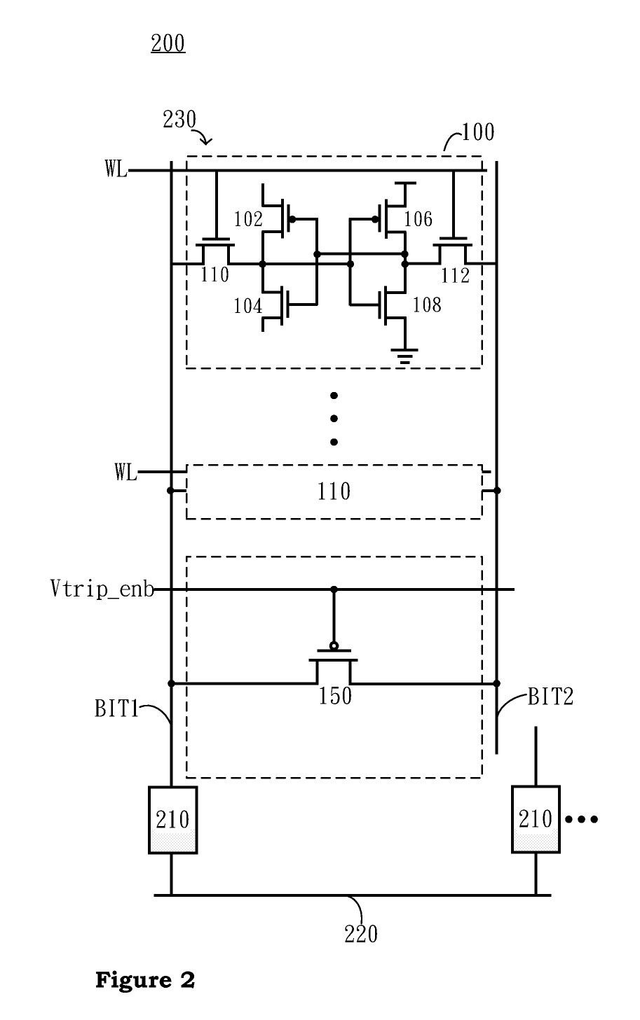

Please referring to FIG. 2, which is an illustration of the SRAM Array consisted of the SRAM according to FIG. 1. As shown in FIG. 2, the SRAM Array 200 includes a plurality of SRAM 100 shown in FIG. 1, and the state control transistor 150. In this embodiment, a plurality of SRAM 100 located at the same column forms a SRAM Array 230. Among these, the source of every first pass-gate transistor 110 is coupled with the first bit line BIT1, and the source of every second pass-gate transistor 112 is coupled with the second bit line BIT2. The state control transistor 150 is coupled between the first bit line BIT1 and the second bit line BIT2 by the drain and the source. The gate of the state control transistor 150 is coupled with a control voltage Vₜᵣᵢₚ_{_{—}}_{enb}. The short circuit of the first bit line BIT1 and the second bit line BIT2 is controlled by the control voltage Vₜᵣᵢₚ_{_{—}}_{enb}, and then the trip voltage Vₜᵣᵢₚ is measured. For example, when the input of control voltage Vₜᵣᵢₚ_{_{—}}_{enb} is 0, the first bit line BIT1 and the second bit line BIT2 will form a short circuit, in order to measure the trip voltage Vₜᵣᵢₚ. In addition, the gate of the first pass-gate transistor 110 and the gate of the second pass-gate transistor 112 are coupled with the first word line WL. It is able to measure the trip voltage Vₜᵣᵢₚ of every SRAM 100 in the SRAM Array 230 by switching the first word line WL.

Please referring to FIG. 2 continuously, the SRAM Array 200 further includes a plurality of multiplier 210 and a plurality column of SRAM Array 230. The first bit line BIT1 of every SRAM Array 230 is coupled with a multiplier 210. A plurality of 210 is coupled with a bus 220. The SRAM Array 200 includes a plurality column of SRAM Array 230, which share a bus 220. The selected SRAM Array 230 is controlled by switching the multiplier 210.

As the embodiment shown in FIG. 2, the stress mode of the SRAM

Array 200 for measuring the Bias Temperature Instability (BTI) includes the PMOS mode, the NMOS(I) mode and the NMOS(II) mode. The BTI of PMOS and NMOS can be measured through different stress mode. Among these, the PMOS mode: the first word line WL=Vₜᵣₑₛₛ, the voltage source VDD=Vₜᵣₑₛₛ, the first bit line BIT1=0, the second bit line BIT2 is floating. The NMOS(I) mode: the first word line WL=Vₜᵣₑₛₛ, the voltage source VDD=Vₜᵣₑₛₛ, the first bit line BIT1=0, the second bit line BIT2=Vₜᵣₑₛₛ. The NMOS(II) mode: the first word line WL=Vₜᵣₑₛₛ, the voltage source VDD=Vₜᵣₑₛₛ, the first bit line BIT1=Vₜᵣₑₛₛ, the second bit line BIT2 is floating, and a voltage Vₜᵣₑₛₛ is applied on the GND.

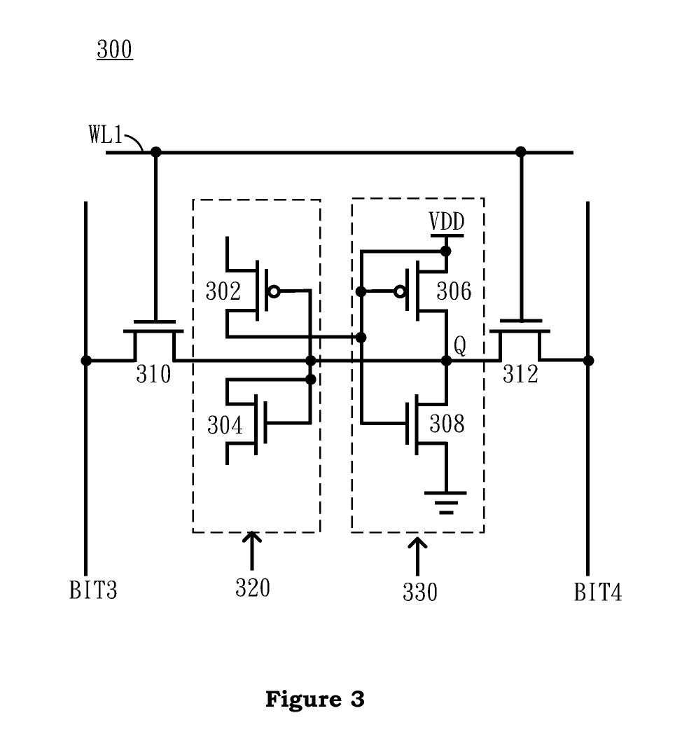

Please referring to the embodiment in FIG. 3, which is another illustration according to the SRAM of the present invention. In this embodiment, the SRAM 300 is used to measure the read disturb voltage V_{read}. The difference between this embodiment (FIG. 3) and the above embodiment (FIG. 1) is that the gate of the second pull-up transistor 306 in this embodiment is coupled with the source of the second pull-up transistor 306. The drain of the first pass-gate transistor 310 is coupled with the drain of the second pull-up transistor 312 and the drain of the second pull-down transistor 312. The source of the second pull-up transistor 312 and the source of the second pull-down transistor 312 are coupled with the voltage source VDD. And, the drain of the first pull-down transistor 304 is coupled with the source of the first pull-down transistor 304 and the gate of the first pull-up transistor 306. The first pull-up transistor 302 and the first pull-down transistor 304 in the first inverter 320 are shown by the gray lines. It means the first inverter 320 and the second inverter 330 are floating.

Please referring to FIG. 3 continuously, the SRAM 300 includes a first inverter 320, a second inverter 330, and a first pass-gate transistor consisted of a first pull-up transistor 302 and a first pull-down transistor 304. The second inverter 330 is consisted of the second pull-up transistor 306 and the second pull-down transistor 308. The drain of the first pass-gate transistor 310 is coupled with the gate of the second pull-up transistor 306 and the gate of the second pull-down transistor 308. The gate of the first pass-gate transistor 310 is coupled with the second world line WL1. The source of the first pass-gate transistor 310 is coupled with the third bit line BIT3. The drain the second pass-gate transistor 312 is coupled with the drain of the second pull-up transistor 306 and the drain of the second pull-down transistor 308. The gate of the second pass-gate transistor 312 is coupled with the second world line WL1. The source of the second pass-gate transistor 312 is coupled with the fourth bit line BIT4.

It has to describe that in the embodiment SRAM 300 shown in FIG. 3, the first pull-up transistor 302 and the second pull-up transistor 306 are P-type metal-oxide-semiconductor (PMOS) transistors. The first pull-down transistor 304, the second pull-down transistor 308, the first pass-gate transistor 310 and the second pass-gate transistor 312 are N-type metal-oxide-semiconductor (NMOS) transistors.

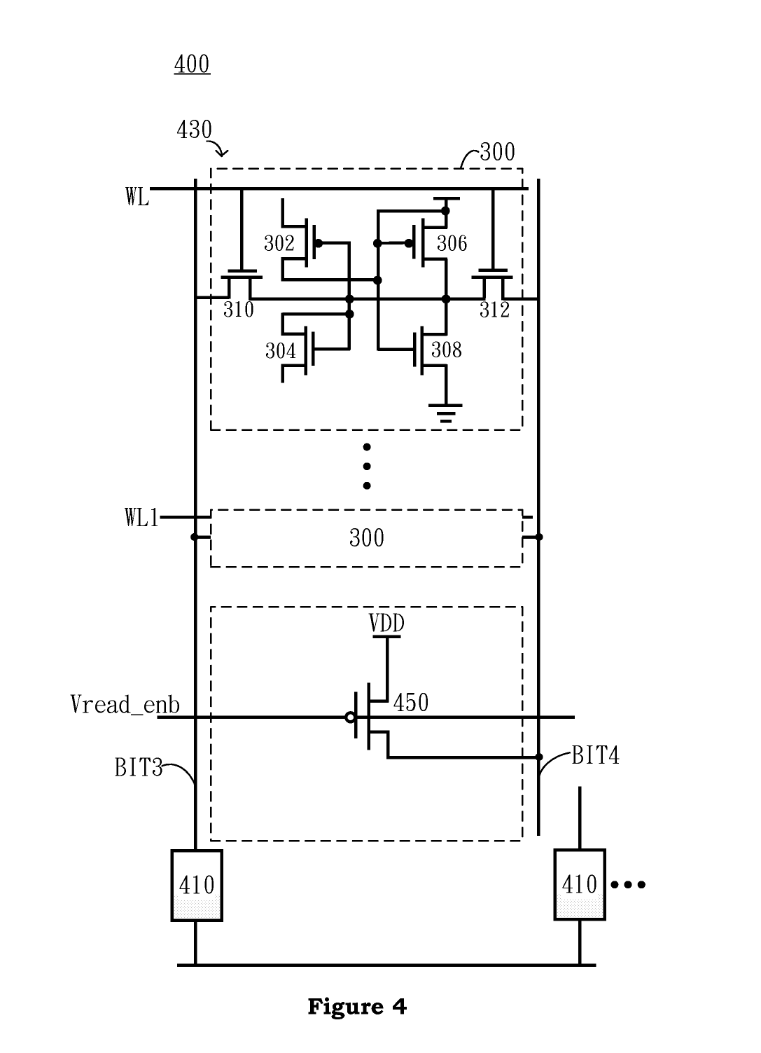

Please referring to FIG. 4, which is an illustration of the SRAM Array consisted of the SRAM according to FIG. 3. As shown in FIG. 4, the SRAM Array 400 includes a plurality of SRAM 300 shown in FIG. 3, and the state control transistor 350. In this embodiment, a plurality of SRAM 300 located at the same column forms a SRAM Array 330. Among these, the source of every first pass-gate transistor 310 is coupled with the third bit line BIT3, and the source of every second pass-gate transistor 312 is coupled with the fourth bit line BIT4. The drain of the state control transistor 450 is coupled with the third bit line BIT3, and the source of the state control transistor 450 is coupled with the fourth bit line BIT4. The gate of the state control transistor 450 is coupled with a control voltage V_{read}_{_{—}}_{enb}, the fourth bit line BIT4 is controlled by the control voltage Vₜᵣᵢₚ_{_{—}}_{enb}, and then the read disturb voltage V_{read} is measured. For example, when the input of control voltage Vₜᵣᵢₚ_{_{—}}_{enb} is 0, the fourth bit line BIT4 is located at high potential, in order to measure read disturb voltage V_{read}. When the second pass-gate transistor 312 is opened, the read disturb voltage V_{read} is stored at the node Q. When the first pass-gate transistor 310 is opened, the read disturb voltage V_{read} will be transmitted to the third bit line BIT3. In addition, the gate of the first pass-gate transistor 310 and the gate of the second pass-gate transistor 312 are coupled with the second word line WL1. It is able to measure the trip voltage Vₜᵣᵢₚ of every SRAM 300 in the SRAM Array 230 by switching the second word line WL1.

Please referring to FIG. 4 continuously, the SRAM Array 400 further includes a plurality of multiplier 410 and a plurality column of SRAM Array 430. The third bit line BIT3 of every SRAM Array 430 is coupled with a multiplier 410. A plurality of 410 is coupled with a bus 420. The SRAM Array 400 includes a plurality column of SRAM Array 430, which share a bus 420. The selected SRAM Array 430 is controlled by switching the multiplier 410.

As the embodiment shown in FIG. 4, the stress mode of the SRAM Array 400 for measuring the Bias Temperature Instability (BTI) includes the NMOS(I) mode and the NMOS(II) mode. Among these, the NMOS(I) mode: the second word line WL1=0, the voltage source VDD=Vₜᵣₑₛₛ, the third bit line BIT3 is floating, the fourth bit line BIT4 is floating. The NMOS(II) mode: the second word line WL1=0, the voltage source VDD=Vₜᵣₑₛₛ, the third bit line BIT3 is floating, the fourth bit line BIT4 is floating, and a voltage −Vₜᵣₑₛₛ is applied on the GND.

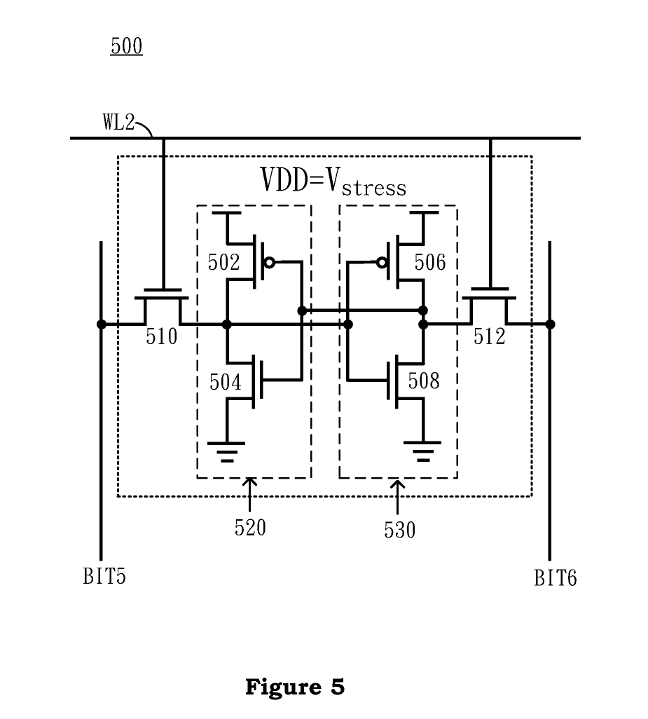

Please refering to the embodiment in FIG. 5, which is another illustration according to the SRAM of the present invention. In this embodiment, the SRAM 500 is used to measure the write margin WM. The difference between this embodiment (FIG. 5) and the above embodiment (FIG. 1) is that the first inverter 520 is coupled with the second inverter 530. The gate of the first pull-up transistor 502 in this embodiment is coupled with the gate of the first pull-down transistor 504 and the drain of the second pull-up transistor 506. The gate of the first pull-up transistor 502 is coupled with the gate of the first pull-down transistor 504. The drain of the first pull-up transistor 502 is coupled with the drain of the first pull-down transistor 504, and the drain of the first pull-up transistor 502 is coupled with the drain of the first pass-gate transistor 510, the gate of the second pull-up transistor 506 and the gate of the second pull-down transistor 508. The SRAM 500 measures the write margin WM by controlling the fifth bit line BITS, the sixth bit line BIT6, the third word line WL2, the GND and the input voltage of voltage source VDD.

In the embodiment of FIG. 5, only a P-type metal-oxide-semiconductor (PMOS) transistors and a N-type metal-oxide-semiconductor (NMOS) transistors are stressed at the same time.

Please referring to FIG. 5, the stress mode of the SRAM Array 500 for measuring the Bias Temperature Instability (BTI) includes the stress mode(I) and the stress mode(II). Among these, the stress mode(I): the third word line WL2=0, the voltage source VDD=Vₜᵣₑₛₛ, the fifth bit line BITS is floating, the sixth bit line BIT6 is floating. The stress mode(II): the third word line WL2=0, the voltage source VDD=Vₜᵣₑₛₛ, the fifth bit line BITS is floating, the sixth bit line BIT6 is floating, and a voltage −Vₜᵣₑₛₛ is applied on the GND.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A SRAM based on 6 transistor structure, comprising:
a first inverter, including a first pull-up transistor and a first pull-down transistor;
a second inverter, including a second pull-up transistor and a second pull-down transistor, a gate of the second pull-up transistor being coupled with the gate of the second pull-down transistor, a drain of the second pull-up transistor being coupled with a drain of the second pull-down transistor, a source of the second pull-up transistor being coupled with a voltage source, and a source of the second pull-down transistor being coupled with a GND;
a first pass-gate transistor, a drain of the first pass-gate transistor being coupled with the gate of the second pull-up transistor and the gate of the second pull-down transistor, a gate of the first pass-gate transistor being coupled with a first word line, and a source of the first pass-gate transistor being coupled with a first bit line; and
a second pass-gate transistor, a drain of the second pass-gate transistor being coupled with the drain of the second pull-up transistor and the drain of the second pull-down transistor, a gate of the second pass-gate transistor being coupled with a first word line, and the source of a second pass-gate transistor being coupled with a second bit line;
wherein the SRAM measuring a trip voltage, a read disturb voltage and a write margin by controlling the first bit line, the second bit line, the first word line, the GND and an input voltage of the voltage source.

2. The SRAM according to claim 1, wherein the first pull-up transistor and the second pull-up transistor comprise P-type metal-oxide- semiconductor transistors.

3. The SRAM according to claim 1, wherein the first pull-down transistor, the second pull-down transistor, the first pass-gate transistor and the second pass-gate transistor comprise N-type metal-oxide-semiconductor transistors.

4. The SRAM according to claim 1, wherein the first pull-up transistor and the first pull-down transistor are floating.

5. The SRAM according to claim 1, wherein the gate of the second pull-up transistor is coupled with the source of second pull-up transistor, the gate and the drain of the second pull-up transistor are coupled with the voltage source, the drain of the first pass-gate transistor is coupled with the drain of the second pull-up transistor and the drain of the second pull-down transistor, wherein, the SRAM measures the read disturb voltage by controlling the first bit line, the second bit line, the first word line, the GND and the input voltage of voltage source.

6. The SRAM according to claim 5, wherein the first pull-up transistor and the first pull-down transistor are floating.

7. The SRAM according to claim 1, wherein the gate of the first pull-up transistor is coupled with the gate of the first pull-down transistor and the drain of the second pull-up transistor, the gate of the first pull-up transistor is coupled with the gate of the first pull-down transistor, the drain of the first pull-up transistor is coupled with the drain of the first pull-down transistor, the drain of the first pull-up transistor is coupled with the drain of the first pass-gate transistor, the gate of the second pull-up transistor is coupled with the gate of the second pull-down transistor, the source of the first pull-up transistor is coupled with the voltage source, the source of the second pull-down transistor is coupled with the GND, wherein, the SRAM measures the write margin by controlling the first bit line, the second bit line, the first word line, the GND and the input voltage of voltage source.
